(19) United States
(12) Patent Application Publication
(10) Pub. No.: US 2005/0257747 A1
(43) Pub. Date: Nov. 24, 2005

(54) Worktable device, film formation apparatus, and film formation method for semiconductor process

(76) Inventors: Satoshi Wakabayashi, Nirasaki-shi (JP); Shinya Okabe, Nirasaki-shi (JP); Seishi Murakami, Nirasaki-shi (JP); Masato Morishima, Nirasaki-shi (JP); Kunihiro Tada, Nirasaki-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/192,047

(22) Filed: Jul. 29, 2005

Related U.S. Application Data
(63) Continuation-in-part of application No. PCT/JP03/16961, filed on Dec. 26, 2003.

(30) Foreign Application Priority Data
Jan. 31, 2003 (JP) 2003-024264
Jul. 18, 2003 (JP) 2003-199377

(51) Int. Cl. C23C 16/00

(52) U.S. Cl. 118/728

(57) ABSTRACT

A worktable device is disposed inside a film formation process container for a semiconductor process. The worktable device includes a worktable including a top surface to place a target substrate thereon, and a side surface extending downward from the top surface, and a heater disposed in the worktable and configured to heat the substrate through the top surface. A CVD pre-coat layer covers the top surface and the side surface of the worktable. The pre-coat layer has a thickness not less than a thickness which substantially saturates the amount of radiant heat originating from heating of the heater and radiated from the top surface and the side surface of the worktable.

### CROSS-REFERENCE TO RELATED APPLICATIONS

This is a Continuation-in-Part Application of PCT Application No. PCT/JP03/16961, filed Dec. 26, 2003, which was published under PCT Article 21(2) in Japanese.

This application is based upon and claims the benefit of priority from prior Japanese Patent Applications No. 2003-024264, filed Jan. 31, 2003; and No. 2003-199377, field Jul. 18, 2003, the entire contents of both of which are incorporated herein by reference.

### BACKGROUND OF THE INVENTION

1. Field of the Invention

The present invention relates to a worktable device, film formation apparatus, and film formation method for a semiconductor process. The term “semiconductor process” used herein includes various kinds of processes which are performed to manufacture a semiconductor device or a structure having wiring layers, electrodes, and the like to be connected to a semiconductor device, on a target substrate, such as a semiconductor wafer or a glass substrate used for an LCD (Liquid Crystal Display) or FPD (Flat Panel Display), by forming semiconductor layers, insulating layers, and conductive layers in predetermined patterns on the target substrate.

2. Description of the Related Art

In manufacturing semiconductor integrated circuits, a number of predetermined semiconductor devices are formed by repeating film formation and pattern etching on a semiconductor wafer, such as a silicon substrate. In order to connect the devices or to form electrical contact with the devices, inter-connection layers are used each along with a barrier layer disposed therebelow. The barrier layer is utilized to prevent an inter-connection material and a contact metal from causing counter diffusion relative to each other, or to prevent an inter-connection layer from separating from an underlying layer. The barrier layer should be made of a material with good adhesive-ness, heat resistance, barrier property, and corrosion resistance, as well as low electrical resistivity, as a matter of course. In order to meet these requirements, a TiN film is frequently used as the material of a barrier layer.

Where a barrier layer consisting of a TiN film is formed, TiCl₄ gas and NH₃ gas are used to deposit a TiN film with a predetermined thickness by CVD (Chemical Vapor Deposition). In this case, before a semiconductor wafer is loaded into a process container, a pre-coat layer consisting of a TiN film is formed on the surface of a worktable in advance. The pre-coat layer is utilized to maintain thermal planar uniformity in the wafer, and to prevent metal contamination from metal elements contained in the worktable.

The pre-coat layer is removed every time the process container is cleaned. Accordingly, a pre-coat layer is formed on the surface of the worktable after the cleaning and before a semiconductor wafer is loaded into the process container. For example, a TiN pre-coat layer is formed by a step of forming a Ti film by CVD, and a step of nitriding the Ti film by NH₃ gas.

In this respect, the following three publications are listed as conventional arts.
Patent publication 1: Jpn. Pat. Appln. KOKAI Publication No. 10-321558,
Patent publication 2: Jpn. Pat. Appln. KOKAI Publication No. 2001-144033 (see Paragraph numbers 0013 to 0020, and FIGS. 1 and 2), and
Patent publication 3: Jpn. Pat. Appln. KOKAI Publication No. 2001-192828.

Patent publications 1 and 2 disclose a technique for forming a pre-coat layer consisting of a Ti film or TiN film on the surface of a worktable. Patent publication 3 discloses a problem in a film formation process after an idling operation, in which the process is unstable when the first substrate is processed, thereby deteriorating the reproducibility and inter-substrate uniformity of film thickness. Patent publication 3 discloses a technique for solving this problem by supplying either a source gas or reduction gas for a short period of time after the idling operation and immediately before the film formation process is performed on the first substrate.

As regards single-substrate processes for forming a Ti film, it is necessary to improve the planar uniformity and inter-substrate uniformity in the film thickness of the Ti film (with a very small film thickness), in order to decrease the film thickness and to improve electrical characteristics of semiconductor devices. The term “planar uniformity” is the uniformity in the film thickness of the Ti film on one wafer. The term “inter-substrate uniformity” is uniformity in the film thickness of the Ti film among a plurality of wafers (which may be also referred to as reproducibility).

Conventionally, in order to increase the operation rate of an apparatus, a pre-coat layer with a small thickness is formed on a worktable before a film formation process is performed on a wafer. For example, the thickness of a conventional pre-coat layer is about 0.36 μm. This pre-coat layer is formed by repeating a predetermined cycle about 18 times, each cycle comprising a step of depositing a very thin Ti film by plasma CVD, and a step of nitriding the Ti film. In this case, however, a problem has been found in that the film thickness and resistivity of a Ti film deposited on the first several wafers are inconstant and vary.

### BRIEF SUMMARY OF THE INVENTION

An object of the present invention is to provide a worktable device, film formation apparatus, and film formation method for a semiconductor process, which can improve at least the inter-substrate uniformity of a film formed on target substrates.

Another object of the present invention is to provide a film formation method for a semiconductor process, which can improve the planar uniformity and inter-substrate uniformity of a film formed on target substrates.

According to a first aspect of the present invention, there is provided a worktable device configured to be installed in a film formation process container for a semiconductor process, the device comprising:
a worktable including a top surface to place a target substrate thereon, and a side surface extending downward from the top surface;
a heater disposed in the worktable and configured to heat the substrate through the top surface; and
a CVD pre-coat layer covering the top surface and the side surface of the worktable, the pre-coat layer having a thickness not less than a thickness which substantially saturates amount of radiant heat originating from heating of the heater and radiated from the top surface and the side surface.

According to a second aspect of the present invention, there is provided a film formation apparatus for a semiconductor process, comprising:
a process container configured to accommodate a target substrate;
a gas supply section configured to supply a process gas into the process container;
a gas exhaust section configured to exhaust gas inside the process container;
a worktable disposed inside the process container and including a top surface to place the target substrate thereon, and a side surface extending downward from the top surface;
a heater disposed in the worktable and configured to heat the substrate through the top surface; and
a CVD pre-coat layer covering the top surface and the side surface of the worktable, the pre-coat layer having a thickness not less than a thickness which substantially saturates amount of radiant heat originating from heating of the heater and radiated from the top surface and the side surface.

According to a third aspect of the present invention, there is provided a film formation method for a semiconductor process, comprising:
preparing a film formation apparatus, which comprises a process container configured to accommodate a target substrate, a gas supply section configured to supply a process gas into the process container, a gas exhaust section configured to exhaust gas inside the process container, a worktable disposed inside the process container and including a top surface to place the target substrate thereon, and a side surface extending downward from the top surface, and a heater disposed in the worktable and configured to heat the substrate through the top surface;
performing a CVD process while supplying a pre-process gas into the process container, to form a CVD pre-coat layer covering the top surface and the side surface of the worktable, the pre-coat layer having a thickness not less than a thickness which substantially saturates amount of radiant heat originating from heating of the heater and radiated from the top surface and the side surface;
loading the substrate into the process container and placing the substrate on the top surface of the worktable, after forming the pre-coat layer; and
performing a main film formation process while supplying a main process gas into the process container, to form a film on the substrate placed on the worktable.

According to a fourth aspect of the present invention, there is provided a method according to the third aspect, wherein
forming the pre-coat layer comprises a film formation step of forming a TiN film by thermal CVD,
the gas supply section comprises a showerhead disposed above the worktable,
the main film formation process is performed by plasma CVD, and
the worktable is set at a temperature in the thermal CVD to cause the showerhead to have a temperature substantially the same as that of the showerhead provided by the plasma CVD.

According to a fifth aspect of the present invention, there is provided a film formation method for a semiconductor process, comprising:
preparing a film formation apparatus, which comprises a process container configured to accommodate a target substrate, a gas supply section configured to supply a process gas into the process container, a gas exhaust section configured to exhaust gas inside the process container, a worktable disposed inside the process container and including a top surface to place the target substrate thereon, and an excitation mechanism configured to generate plasma within the process container;
performing a first process by plasma CVD while supplying a first process gas into the process container, wherein the first process gas is a gas that generates ions mostly of a first polarity by ionization;
performing a stabilization process to stabilize a state within the process container after the first process, wherein a stabilization process gas that generates ions mostly of a second polarity opposite to the first polarity by ionization is supplied into the process container and turned into plasma during the stabilization process;
loading the substrate into the process container and placing the substrate on the top surface of the worktable, after the stabilization process; and
performing a main film formation process by plasma CVD while supplying a main process gas into the process container, to form a film on the substrate placed on the worktable.

According to the first to third aspects, since the worktable thermally stabilizes while a film formation process is repeated to process respective target substrates, the reproducibility of the film formation process is improved. Accordingly, the inter-substrate uniformity (reproducibility) of a film formed on the target substrates is improved in terms of characteristics, such as the film thickness and resistivity.

According to the fourth aspect, there is essentially no temperature difference of the showerhead between the pre-coat layer formation step and main film formation process. Accordingly, the planar uniformity (particularly on the first target substrate) and the inter-substrate uniformity of a film formed on the target substrates are improved in terms of characteristics, such as the film thickness and resistivity.

According to the fifth aspect, abnormal electrical discharge is prevented from occurring between the worktable and target substrate. Accordingly, the planar uniformity (particularly on the first target substrate) and the inter-substrate uniformity of a film formed on the target substrates are improved in terms of characteristics, such as the film thickness and resistivity.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a structural view schematically showing a film formation apparatus for a semiconductor process, according to an embodiment of the present invention;

FIGS. 2A to 2C are sectional views respectively showing worktables each with a pre-coat layer formed thereon;

FIGS. 3A to 3D are time charts respectively showing different methods for forming a pre-coat layer;

FIG. 4 is a graph showing the relationship between the film thickness of a pre-coat layer and the power consumption (%) of a resistance heater;

FIG. 5 is a graph showing change in the load position and tune position of a matching circuit, with change in the film thickness of a pre-coat layer;

FIG. 6 is a graph showing change in the resistivity of a Ti film where a wafer is processed by a processing apparatus according to the embodiment and a conventional processing apparatus;

FIG. 7 is a graph showing the influence of the relationship between a pre-coat layer formation temperature and a wafer film formation temperature, on the pre-coat film thickness and inter-substrate uniformity;

FIG. 8 is a graph showing the resistivity of a deposited film obtained by film formation on the first wafer after a processing apparatus undergoes an idling operation for a long period of time;

FIGS. 9A and 9B are explanatory diagrams showing the cause of electrical discharge occurring between a semiconductor wafer and a worktable;

FIGS. 10A and 10B are time charts respectively showing different methods for performing a stabilization process;

FIGS. 11A and 11B are views showing the resistivity of a Ti film formed on the first wafer without the stabilization process and with the stabilization process, respectively;

FIG. 12 is a diagram showing specific process conditions for a pre-coating process;

FIG. 13 is a diagram showing specific process conditions for a stabilization process; and

FIG. 14 is a block diagram schematically showing the structure of a control section.

### DETAILED DESCRIPTION OF THE INVENTION

In the process of developing the present invention, the inventors studied a pre-coat layer formed on a worktable. As a result, the inventors have arrived at the findings given below.

When the thickness of a pre-coat layer reaches a certain thickness (threshold) or more, the amount of radiant heat from the top surface and side surface of a worktable comes to show no change (substantial saturation). The thickness of a pre-coat layer by which the amount of radiant heat is substantially saturated does not depend on the temperature of a worktable, as long as the temperature is within a range commonly used for film formation processes (for example, 350 to 750° C. for nitride films of high melting point metals).

Where the thickness of a pre-coat layer is set to be equal to the threshold or more described above, the amount of radiant heat from the top surface and side surface of a worktable does substantially not change even if by-products are further deposited thereon in processing a wafer. In other words, without regard to the number of repetitions of a single-substrate process on wafers, the amount of radiant heat from the worktable is maintained as a constant condition (thermal stability). Accordingly, a thermal condition of the process can be maintained constant for a plurality of wafers, so as to improve the inter-substrate uniformity of a film formed on the wafers. This will be described later in more detail.

Embodiments of the present invention achieved on the basis of the findings given above will now be described with reference to the accompanying drawings. In the following description, the constituent elements having substantially the same function and arrangement are denoted by the same reference numerals, and a repetitive description will be made only when necessary.

### FIRST EMBODIMENT

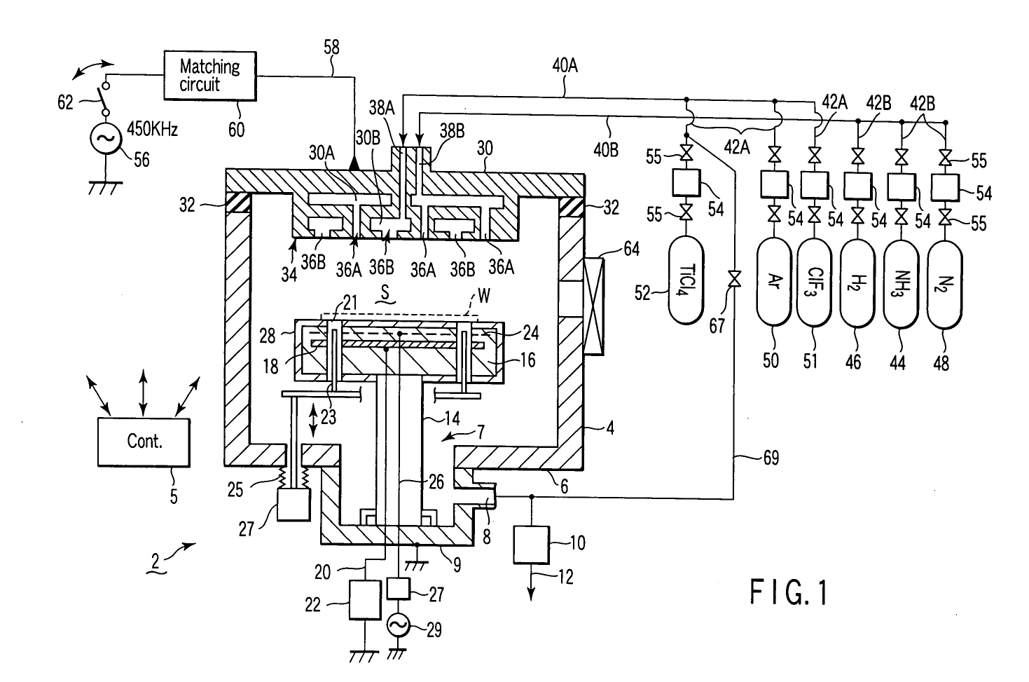

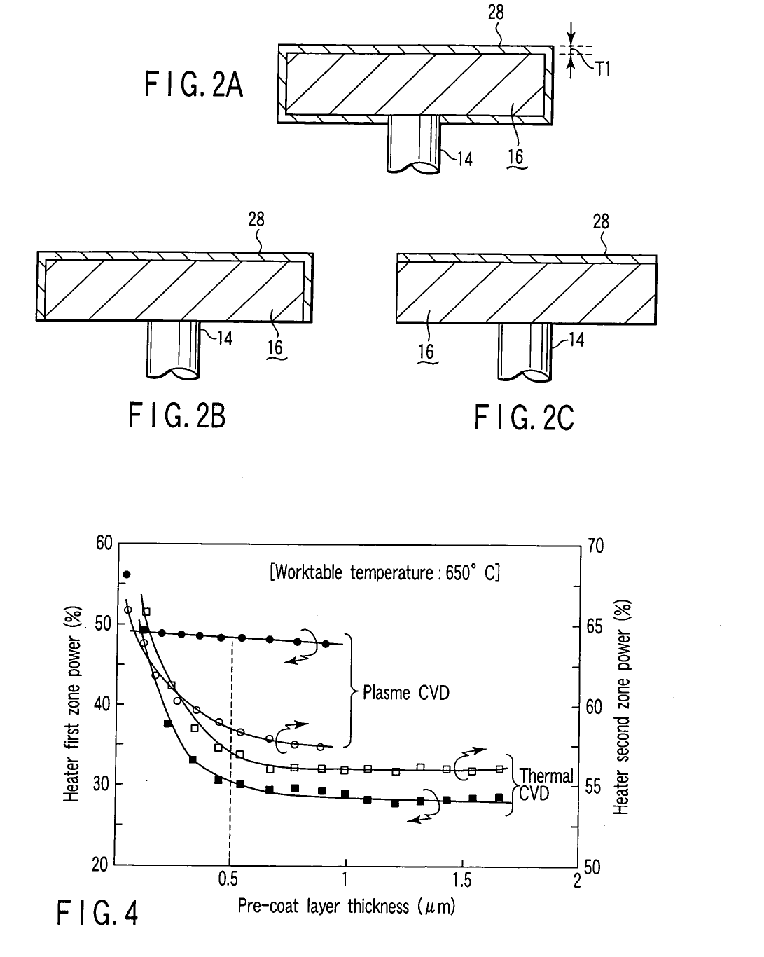

FIG. 1 is a structural view schematically showing a film formation apparatus for a semiconductor process, according to an embodiment of the present invention. FIGS. 2A to 2C are sectional views respectively showing worktables each with a pre-coat layer formed thereon. In this embodiment, an explanation will be given of a case where a pre-coat layer consisting of a TiN-containing film is formed by plasma CVD and a nitridation process, or thermal CVD.

As shown in FIG. 1, the processing apparatus 2 includes a cylindrical process container 4 made of, e.g., Al or an Al alloy material. The process container 4 has an opening 7 at the center of the bottom 6, which is airtightly closed by an exhaust chamber 9 protruding downward. The exhaust chamber 9 has an exhaust port 8 formed on one sidewall and connected to an exhaust system 12 including a vacuum pump 10, so that the atmosphere within the container can be exhausted. With this arrangement, the interior of the process container 4 can be uniformly exhausted through the bottom periphery by the exhaust system 12.

The process container 4 is provided with a worktable 16 disposed therein and formed of a circular plate configured to place a target substrate or semiconductor wafer W thereon. The worktable 16 is supported by a strut 14 extending upward from the bottom 6 of the exhaust chamber 9 into the process container 4. Specifically, the worktable 16 is made of a ceramic material, such as AlN, with a resistance heater 18 embedded therein as heating means. The resistance heater 18 is connected to a power supply 22 through a feed line 20 extending inside the strut 14. The resistance heater 18 is formed of a plurality of heating zones divided (not shown) on a plane, which can be controlled independently of each other. The worktable 16 is provided with lift pins 23 movable up and down through pin holes 21 to assist transfer of a wafer W to and from the worktable 16. The lift pins 23 are moved up and down by an actuator 27, which is connected to the container bottom 6 via a bellows 25.

The worktable 16 is also provided with a lower electrode 24 formed of, e.g., a mesh buried near the top surface. The lower electrode 24 is connected to a matching circuit 27 and an RF power supply 29 through a feed line 26. An RF power is applied to the lower electrode 24 to give a self bias to the target substrate. The surface of the worktable 16 is countersunk to form a recess for guiding the target substrate.

The surface of the worktable 16 is covered with a pre-coat layer 28 to improve the thermal stability. As shown in FIGS. 1 and 2A, the pre-coat layer 28 is most preferably formed to cover all of the top surface, side surface, and bottom surface. However, a pre-coat layer is formed in a different manner to prevent change in the amount of radiant heat from the worktable in film formation. For example, as shown in FIG. 2B, a pre-coat layer 28 may be formed to cover only the top surface and side surface of the worktable 16. Alternatively, as shown in FIG. 2C, a pre-coat layer 28 may be formed to cover only the top surface of the worktable 16. FIGS. 2A to 2C do not show the resistance heater 18 or the lower electrode 24.

In this embodiment, the pre-coat layer 28 is formed using the same gas as the source gas used for the film formation performed on the semiconductor wafer W in this apparatus. Namely, the pre-coat layer 28 consists of a TiN-containing film. The pre-coat layer 28 is designed to have a thickness T1 not less than a thickness which can substantially saturate the amount of radiant heat originating from heating of the heater 18 and radiated from the top surface, side surface, and bottom surface of the worktable 16 (at least from the top surface and side surface). In other words, the thickness T1 of the pre-coat layer 28 is set to be within a range by which the amount of radiant heat from the worktable remains almost constant, even if the film thickness is changed within the range, as long as the temperature of the worktable is set to be substantially constant.

For example, the thickness T1 of the pre-coat layer 28 is set at 0.4 μm or more, and preferably at 0.5 μm or more. A method of forming this TiN-containing film and the reason for the value of 0.5 μm will be described later. In light of the process throughput, the thickness T1 of the pre-coat layer 28 is preferably set at 20 μm or less.

On the other hand, a showerhead 30 is airtightly attached on the ceiling of the process container 4 through an insulating member 32 to feed necessary process gases. The showerhead 30 faces the top surface of the worktable 16 almost entirely, and a process space S is defined between the showerhead 30 and worktable 16. The showerhead 30 introduces various gases into the process space S in a dispersive state. The showerhead 30 has an injection face 34 on the bottom with a number of injection holes 36A and 36B formed therein to inject gases. The showerhead 30 may be structured to be of a pre-mix type that mixes gases therein, or a post-mix type that separately feeds gases into the process space S where the gases are mixed for the first time. In this embodiment, the showerhead 30 is of the post-mix type, as described below.

The interior of the showerhead 30 is divided into two spaces 30A and 30B. The spaces 30A and 30B respectively communicate with sets of injection holes 36A and 36B. The showerhead 30 has gas feed ports 38A and 38B at the top to respectively feed gases into the spaces 30A and 30B inside the head. The gas feed ports 38A and 38B are respectively connected to supply passages 40A and 40B to supply the gases. The supply passages 40A and 40B are connected to a plurality of branch lines 42A and 42B.

The branch lines 42B on one side are respectively connected to an NH₃ gas source 44 storing NH₃ gas as a process gas, an H₂ gas source 46 storing H₂ gas, and an N₂ gas source 48 storing N₂ gas as an example of an inactive gas. The branch lines 42A on the other side are respectively connected to an Ar gas source 50 storing Ar gas as an example of an inactive gas, a TiCl₄ gas source 52 storing TiCl₄ gas as an example of a film formation gas, and a ClF₃ gas source 51 storing ClF₃ gas as a cleaning gas.

The flow rates of the gases are respectively controlled by flow rate controllers, such as mass flow controllers 54, disposed on the branch lines 42A and 42B. The branch lines 42A and 42B are respectively provided with valves 55, which switch gas supply by opening/closing actions. In this embodiment, gases used for film formation are mixed and supplied through each of the supply passages 40A and 40B. Alternatively, a gas supply structure of a so called post-mix type may be adopted such that part or all of the gases may be respectively supplied through different passages and then mixed in the showerhead 30 or process space S. The branch lines 42A from the TiCl₄ gas source 52 is connected to the exhaust system 12 through a pre-flow line 69 with a switching valve 67 disposed thereon. TiCl₄ gas is caused to flow through the pre-flow line 69 for several seconds to stabilize the flow rate immediately before the gas is supplied into the process container 4.

The showerhead 30 also functions as an upper electrode, and thus is connected to a radio frequency (RF) power supply 56 of, e.g., 450 kHz for plasma generation through a feed line 58. The frequency of the RF power supply 56 is set at a value within a range of, e.g., 450 kHz to 60 MHz. The feed line 58 is provided with a matching circuit 60 for impedance matching and a switch 62 for RF cutoff, disposed thereon in this order. The processing apparatus 2 can function as a thermal CVD apparatus if it is used for performing a process without plasma generation, by cutting off the radio frequency.

A gate valve 64 is disposed on one sidewall of the process container 4 to be opened/closed for wafer transfer. The worktable 16 is provided with a focus ring when utilizing plasma, or a guide ring when performing thermal CVD, disposed thereon, although this is not shown.

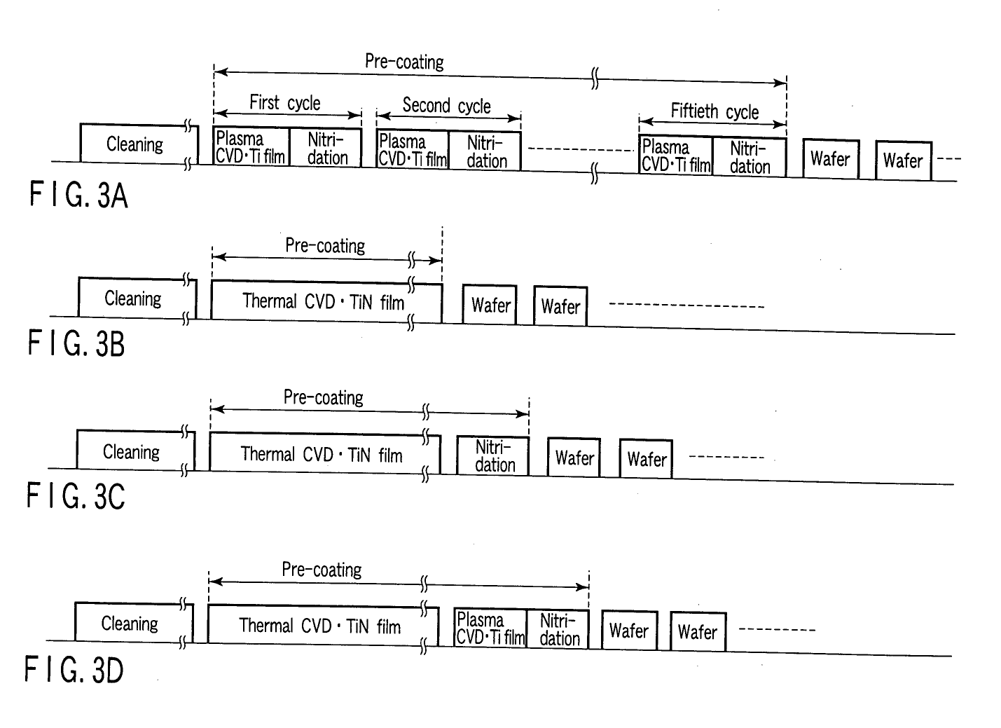

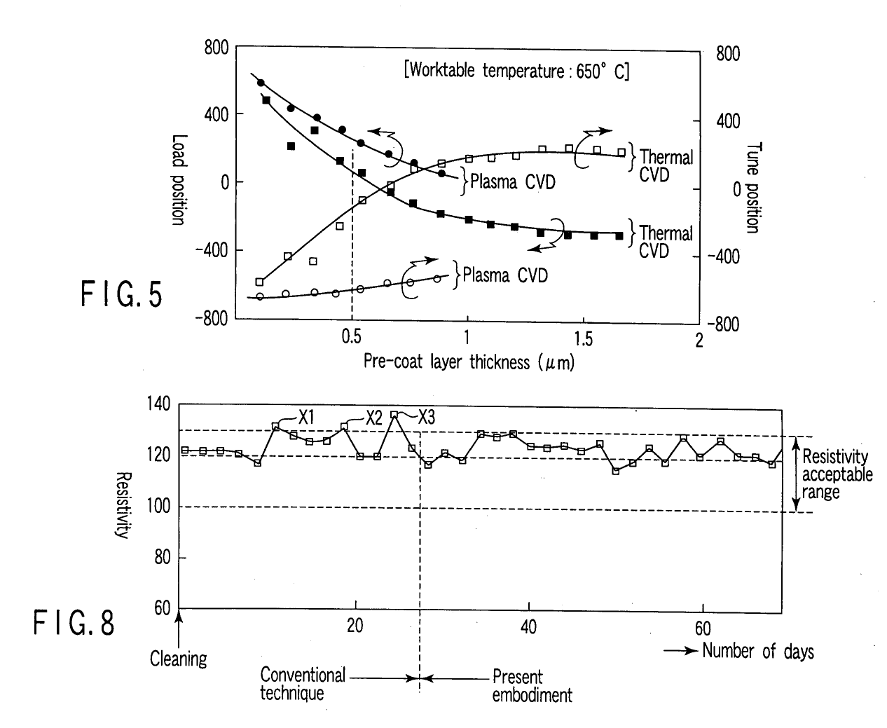

Next, an explanation will be give of a method of forming a pre-coat layer 28, using the processing apparatus described above, with reference to FIGS. 3A to 3D. FIGS. 3A to 3D are time charts respectively showing different methods for forming a pre-coat layer.

At first, a method shown in FIG. 3A will be explained. The process container 4 is airtightly closed first while no semiconductor wafer W is present on the worktable 16 within the process container 4. At this time, for example, the interior of the process container 4 is in a state where all the unnecessary films have been removed by a cleaning process after a film formation process, or it has been subjected to a maintenance process. Accordingly, no pre-coat layer is present on the surface of the worktable 16, and the body of the worktable 16 is exposed. Alternatively, the apparatus may be a newly installed one, and thus has not been used for a process performed within the container 4.

After the process container 4 is airtightly closed, Ar gas and H₂ gas are supplied from the showerhead 30 into the process container 4 at predetermined flow rates. Further, the interior of the process container 4 is vacuum-exhausted by the vacuum pump 10 and maintained at a predetermined pressure.

Furthermore, the worktable 16 is heated and maintained at a predetermined temperature by the resistance heater 18 embedded in the worktable 16. In this state, the switch 62 is turned on to apply an RF power between the showerhead (upper electrode) 30 and worktable (lower electrode) 16, so that the mixture gas of Ar gas and H₂ gas is turned into plasma within the process space S. With this state, TiCl₄ gas is supplied for a short period of time of, e.g., about 5 to 120 seconds, and preferably of 30 to 60 seconds. In this way, a film formation step is performed to deposit a very thin Ti film having a thickness of about 10 nm or more, such as 20 nm, on the surface of the worktable 16 by plasma CVD. Then, while maintaining plasma generation (by supplying Ar/H₂), the supply of TiCl₄ gas is stopped. At the same time, NH₃ gas is supplied for a short period of time of, e.g., about 5 to 120 seconds, and preferably of 30 to 60 seconds. In this way, a nitridation step is performed to nitride the Ti film. As a consequence, one cycle of a process for forming a TiN-containing film is completed.

Then, an inactive gas, such as N₂ gas or Ar gas, is supplied for a short period of time to purge the process gases remaining within the process container 4. Then, the same process for forming a TiN-containing film as described above is repeated for the second to fiftieth cycles, thereby laminating a plurality of thin TiN-containing films. As a consequence, a pre-coat layer 28 consisting of a TiN-containing film is formed to have a thickness of 0.4 μm or more, and preferably of 0.5 μm or more, as a whole. The TiN-containing film may be formed of a Ti film nitrided only at the surface, or may be formed of a TiN film entirely. In consideration of the heat radiation characteristic, it is preferable for the entirety of the film to be a TiN film.

If the thickness of a Ti film deposited by one cycle is too large, it is difficult to sufficiently nitride the Ti film. Accordingly, the maximum thickness of a Ti film deposited by one cycle is preferably set at, e.g., 0.05 μm or less, and more preferably at 0.03 μm or less. However, as the thickness of a TiN-containing film deposited by one cycle is larger, the number of repetitions of the cycle can be smaller. In any case, a pre-coat layer 28 is formed to have a thickness of 0.4 μm or more, and preferably of 0.5 μm or more, as a whole.

If the thickness of the pre-coat layer 28 is set to be larger than the value described above, the amount of radiant heat from the worktable 16 does not change but remains almost constant. In other words, when a TiN-containing film is further deposited on the worktable 16 during a film formation process performed on a wafer, the amount of radiant heat does not change. In consideration of the process throughput, the thickness of the pre-coat layer 28 is set at 20 μm or less, preferably at 2 μm or less, and more preferably at less than 1.0 μm.

The pre-coating process shown in FIG. 3A employs the following process conditions. The flow rate of TiCl₄ gas is set to be about 2 to 100 sccm, and preferably to be 4 to 30 sccm. The flow rate of NH₃ gas is set to be about 50 to 5,000 sccm, and preferably to be 400 to 3,000 sccm. The process pressure is set to be about 66.6 to 1,333 Pa, and preferably to be 133.3 to 933 Pa, throughout the process. The worktable temperature is set to be about 400 to 700° C., and preferably to be 600 to 680° C., throughout the process.

After the pre-coating process is finished as described above, a film formation process of a Ti film is performed on wafers one by one.

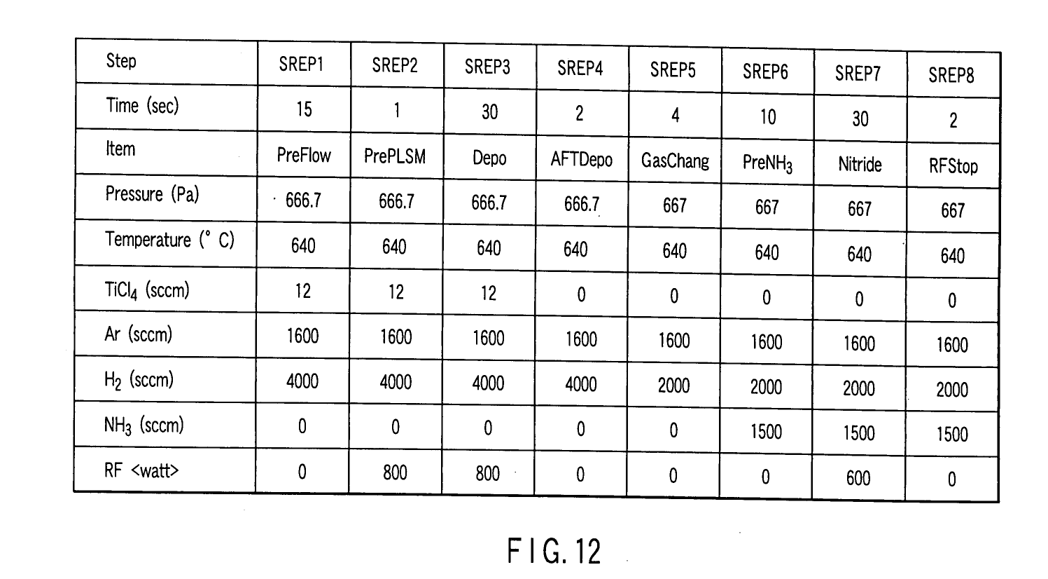

FIG. 12 is a diagram showing specific process conditions for the pre-coating process. As shown in FIG. 12, in STEP 1, i.e., “PreFlow”, Ar gas and H₂ gas are supplied into the process container 4, while the worktable 16 is sufficiently heated and maintained at a predetermined temperature by the resistance heater 18. On the other hand, TiCl₄ gas is exhausted through the pre-flow line 69 to stabilize the flow rate of TiCl₄ gas.

For example, this step employs the following conditions. The process temperature is maintained at 640° C. The process pressure is maintained at a value of 66.6 to 1,333 Pa, such as 666.7 Pa or 667 Pa. The flow rate of TiCl₄ gas is set to be 4 to 50 sccm, such as 12 sccm. The flow rate of Ar gas is set to be 100 to 3,000 sccm, such as 1,600 sccm. The flow rate of H₂ gas is set to be 1,000 to 5,000 sccm, such as 4,000 sccm.

In STEP 2, i.e., “PrePLSM”, an RF(RF) of, e.g., 450 kHz is applied to the upper electrode or showerhead 30 to generate and stabilize plasma for about a couple of seconds (e.g., one second). STEP 2 dose not necessarily require plasma generation, so STEP 2 may be substantially omitted. In STEP 3, i.e., “Depo”, TiCl₄ gas is supplied into the process container 4 to form a Ti film. This film formation time is set to be 30 seconds.

In STEP 4, i.e., “AFTDepo”, the RF application is stopped, and the source gas inside the source gas feed line is exhausted. In STEP 5, i.e., “GasChang”, the flow rate of H₂ gas is decreased from 4,000 sccm to 2,000 sccm and the H₂ gas flow is stabilized, so that the process gases inside the process container 4 are replaced therewith and exhausted. In STEP 6, i.e., “PreNH₃”, prior to plasma generation, NH₃ gas is supplied at a flow rate of 500 to 3,000 sccm, such as 1,500 sccm, into the process container 4, so as to stabilize the flow of NH₃, H₂, and Ar gases.

In STEP 7, i.e., “Nitride”, an RF of 450 kHz is applied to the upper electrode or showerhead 30 to nitride the Ti film by plasma of NH₃, H₂, and Ar gases. This nitridation process time is set to be 5 to 120 seconds, such as 30 seconds. Then, in STEP 8, i.e., “RFStop”, the RF application is stopped, thereby finishing the nitridation process.

Then, such one cycle of the pre-coating process comprising sequential operations described above is repeated a plurality of times, such as 50 times, to form a multi-layered pre-coat layer. Then, a wafer is loaded into the process container 4, and a step of forming a Ti film on the wafer is performed by plasma CVD. By forming the pre-coat layer according to the embodiment, the film thickness, resistivity, planar uniformity, and inter-substrate uniformity can be improved on the first several wafers.

In the film formation method described above, the Ti film is nitrided by plasma, i.e., a plasma nitridation process. However, in place of the plasma nitridation process, a thermal nitridation process without plasma may be employed. According to this thermal nitridation process, a Ti film is formed by plasma CVD, and then the switch 62 is turned off to stop the RF power application. Further, a gas containing N (nitrogen), such as NH₃ gas, is supplied, while TiCl₄ gas is stopped and Ar gas and H₂ gas are kept supplied, to perform a nitridation process. Alternatively, NH₃ gas and H₂ gas may be supplied at predetermined flow rates to perform a thermal nitridation process without plasma. For example, the gas containing nitrogen may be mixed with MMH (monomethylhydrazine) or may consist of MMH.

The thermal nitridation process employs the following process conditions. The flow rate of NH₃ gas is preferably set to be about 5 to 5,000 sccm. The flow rate of H₂ gas is preferably set to be about 50 to 5,000 sccm. The flow rate of Ar gas is preferably set to be about 50 to 2,000 sccm. The flow rate of N₂ gas is preferably set to be about 50 to 2,000 sccm. The flow rate of MMH gas is preferably set to be about 1 to 1,000 sccm. The pressure and worktable temperature are the same as those of the film formation step performed by plasma CVD. At this time, the thickness of the pre-coat film is preferably set to be about 0.4 to 2 μm, and more preferably to be about 0.5 to 0.9 μm.

Next, a method shown in FIG. 3B will be explained. This method is a method of directly forming a TiN film as a pre-coat film by thermal CVD without plasma.

Specifically, unnecessary deposited substances inside the process container 4 are cleaned while no wafer is loaded in the process container 4. Then, a TiN film is directly formed by thermal CVD without plasma. At this time, TiCl₄ gas, NH₃ gas, and N₂ gas are used as film formation gases. Since the reaction rate of this TiN film formation by thermal CVD is high, the pre-coating process can be performed for a short period of time at a high film formation rate. Further, since the step coverage is good (high rate), it is possible to form a TiN film not only on the top surface of the worktable 16, but also sufficiently on the side surface and bottom surface.

Where a pre-coat film of a TiN film is formed by thermal CVD, the pre-coat layer 28 can be formed in one processing to have a thickness of 0.5 μm, without repeating a process cycle as in the method shown in FIG. 3A. In this case, the thickness of the pre-coat layer 28 is preferably set to be 0.4 to 2 μm with which the amount of radiant heat from the worktable 16 does not change. Further, in consideration of the process throughput, the thickness of the pre-coat layer 28 is set to be 20 μm or less, and preferably less than 1.0 μm, such as 0.5 to 0.9 μm.

According to the method shown in FIG. 3A, the pre-coating process takes about 64 minutes. According to the method shown in FIG. 3B, the pre-coating process can be significantly shortened to about 34 minutes. The pre-coating process shown in FIG. 3B employs the following process conditions. The flow rate of TiCl₄ gas is set to be about 5 to 100 sccm. The flow rate of NH₃ gas is set to be about 5o to 5,000 sccm. The flow rate of N₂ gas is set to be about 50 to 5,000 sccm. The pressure, worktable 16 temperature, and pre-coat film thickness are the same as those of the case explained with reference to FIG. 3A.

The method shown in FIG. 3B may be modified as shown in FIG. 3C. According to the method shown in FIG. 3C, a TiN film is directly formed by thermal CVD, as in the case explained with reference to FIG. 3B. Then, a nitridation process using plasma, or a thermal nitridation process (see FIG. 3A) without plasma is performed for a short period of time. As a consequence, the surface of the pre-coat layer 28 is more effectively stabilized. The process conditions and pre-coat film thickness are the same as those described above.

The method shown in FIG. 3B may be modified as shown in FIG. 3D. According to the method shown in FIG. 3D, a TiN film is directly formed by thermal CVD, as in the case explained with reference to FIG. 3B. Then, the cycle shown in FIG. 3A is performed at least once, wherein this cycle comprises a film formation step of forming a Ti film by plasma CVD, and a nitridation step of nitriding the Ti film to form a TiN-containing film. As a consequence, the surface of the pre-coat layer 28 is more effectively stabilized.

Further, the methods shown in FIGS. 3B, 3C and 3D may be modified as follows. (1) In the method shown in FIG. 3B, the time period of one step for forming a TiN film by thermal CVD may be shortened. In this case, the film thickness obtained by one cycle is smaller, such as 5 to 50 nm, and preferably 20 to 30 nm, and this TiN film is repeatedly formed. (2) In the method shown in FIG. 3C, a cycle comprising a TiN film formation step and a nitridation step performed for a short period of time may be repeated a plurality of times to form a pre-coat layer 28 with a predetermined thickness. (3) In the method shown in FIG. 3D, a cycle comprising a TiN film formation step, a Ti film formation step by plasma CVD, and a nitridation step performed for a short period of time may be repeated a plurality of times to form a pre-coat layer 28 with a predetermined thickness. In these cases, the thickness of the pre-coat layer 28 is preferably set to be, e.g., 0.4 to 2 μm.

Next, an explanation will be given of the relationship between the thickness of the pre-coat layer 28 on the worktable 16 and reproducibility of the thickness of a TiN film deposited on semiconductor wafers. As described above, the pre-coat layer 28 is designed to have a thickness not less than a thickness which can substantially saturate the amount of radiant heat originating from heating of the heater 18 and radiated from the top surface, side surface, and bottom surface of the worktable 16. In other words, the thickness of the pre-coat layer 28 is set to be within a range by which the amount of radiant heat from the worktable 16 remains almost constant, even if the film thickness is changed within the range, as long as the temperature of the worktable is set to be substantially constant.

According to the conventional technique, a Ti film with a predetermined film thickness is formed on the surface of a worktable and is then nitrided to form a pre-coat film, each by one operation, while no wafer is placed in a process container. Then, a semiconductor wafer is loaded, and a Ti film is formed on the surface of the wafer by plasma CVD, and is then nitrided to form a TiN film. At this time, in the early stage of the process, the temperature of the showerhead 30 increases with increase in the number of processed wafers, and then becomes almost constant when the number of processed wafers reaches a certain value.

In this case, the temperature of the showerhead 30 significantly varies, depending on change in heat quantity due to plasma formed within the process space S, and change in the amount of radiant heat from the worktable 16. As the temperature of the showerhead 30 varies, the quantity of precursors (TiClx: X=1 to 3) of TiCl₄ gas consumed near here fluctuates. As a consequence, the uniformity and reproducibility of the film thickness and resistivity of a Ti film formed on wafers are deteriorated. Accordingly, in order to improve the reproducibility of the Ti film formation process, it is necessary to stabilize the amount of radiant heat from the worktable 16.

FIG. 4 is a graph showing the relationship between the film thickness of a pre-coat layer and the power consumption (%) of a resistance heater. This data shows the power consumption of the resistance heater 18, obtained when a pre-coat layer was formed in various film thicknesses on the worktable 16, while the temperature of the worktable 16 was kept at a constant temperature of 650° C. with high accuracy. In the case shown in FIG. 4, the resistance heater is formed of a first zone and a second zone, and their power consumption is indicated as a percentage relative to the full power.

As shown in FIG. 4, where the film thickness of the pre-coat layer is small, the power consumption of the resistance heater 18 greatly changes with change in the film thickness. This means that, since the temperature of the worktable 16 is kept at a constant temperature of 650° C., the amount of radiant heat from the worktable 16 itself greatly changes. When the film thickness of the pre-coat layer reaches 0.5 μm, the power consumption becomes almost stable within a certain fluctuation range. In other words, where the film thickness of the pre-coat layer is 0.5 μm or more, the amount of radiant heat from the worktable 16 remains almost constant (substantially saturated).

Further, the matching action of the matching circuit was examined to study the matching of plasma within the process container 4 relative to the film thickness of the pre-coat layer changed as described above. FIG. 5 is a graph showing change in the load position and tune position of the matching circuit 60, with change in the film thickness of a pre-coat layer. The load position denotes the matching position of a variable inductor, and the tune position is the matching position of the variable capacitor. In the matching circuit 60, when a RF power of a predetermined level is applied, the impedance is automatically adjusted to cause the reflection wave to be zero. At this time, the load position and tune position fluctuate.

As shown in FIG. 5, where the film thickness of the pre-coat layer is as thin as less than 0.5 μm, the matching greatly changes, and thus the matching of plasma within the process container 4 greatly changes. Where the film thickness is as thick as about 0.5 μm or more, the matching of plasma becomes stable with very small fluctuations. In other words, where the pre-coat layer is not less than 0.5 μm, stable plasma can be generated so that the uniformity and reproducibility of a film formed on wafers are improved.

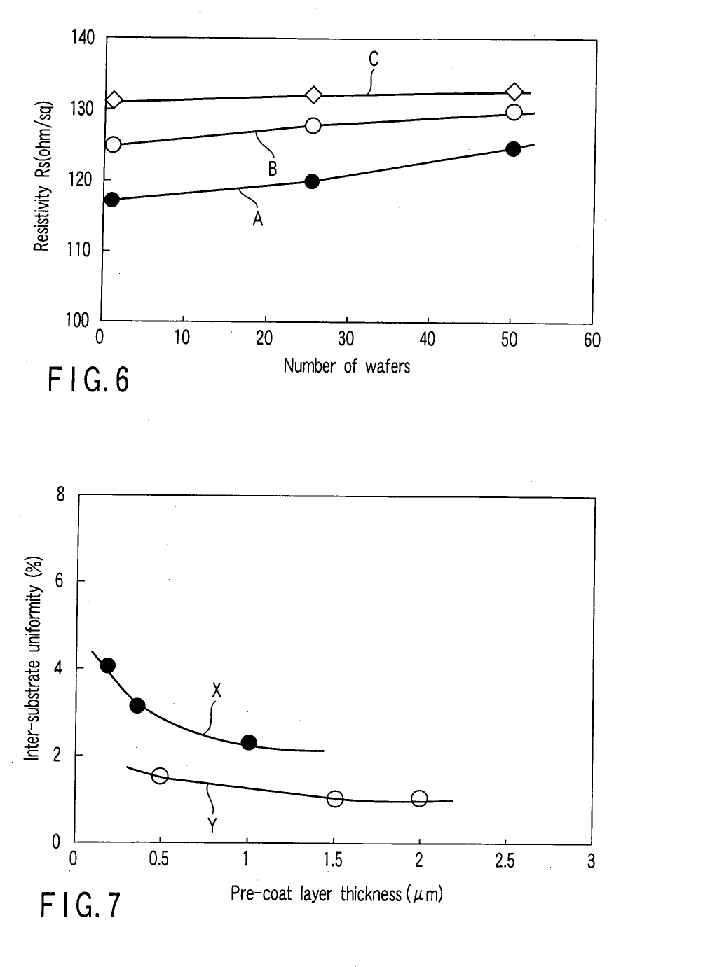

In consideration of the result described above, an experiment was conducted of forming a Ti film on 50 wafers, using a processing apparatus (method) according to this embodiment and a conventional processing apparatus (method). FIG. 6 is a graph showing change in the resistivity of a Ti film where a wafer was processed by a processing apparatus according to the embodiment and a conventional processing apparatus.

In FIG. 6, a line A stands for a conventional processing apparatus provided with a worktable with a pre-coat layer having a thickness of 0.36 μm formed thereon (performing 18 cycles in FIG. 3A). A line B stands for a processing apparatus according to a first present example of this embodiment provided with a worktable with a pre-coat layer having a thickness of 0.5 μm formed thereon by plasma CVD (performing 50 cycles in FIG. 3A). A line C stands for a processing apparatus according to a second present example of this embodiment provided with a worktable with a pre-coat layer having a thickness of 0.5 μm formed thereon by thermal CVD (FIG. 3C).

As shown in FIG. 6, in all the lines A to C, the resistivity gradually increases with increase in the number of processed wafers. Of them, the change of the line A representing the conventional processing apparatus is larger, with a uniformity of 3.1% in resistivity among wafers, which is relatively bad. On the other hand, the change of the line B representing the first present example is smaller, with an improved uniformity of 2.3% in resistivity among wafers, which is relatively good. Further, the change of the line C representing the second present example is much smaller, with a further improved uniformity of 1.5% in resistivity among wafers, which is best.

As described above, the line C representing use of thermal CVD shows a better characteristic than the line B representing use of plasma CVD, because of the following reason. Specifically, the film formation process by thermal CVD has better step coverage, and thus can make the pre-coat layer 28 sufficiently deposited over the worktable 16 down to the bottom surface (see FIG. 2A). Accordingly, the amount of radiant heat from the worktable 16 and the change in radiation can be smaller during the process of wafers.

Further, as shown in FIGS. 3B and 3C, where the pre-coat layer 28 consisting of a TiN film is formed by thermal CVD without plasma, a jumping phenomenon may occur. The jumping phenomenon is a phenomenon in which, when a TiN film is formed by plasma CVD on the first wafer, the resistivity of the film becomes abnormally high on the first wafer. This jumping phenomenon occurs due to the following cause. Specifically, even if the temperature of the worktable 16 is kept at, e.g., 650° C. with high accuracy, the showerhead 30 receives energy from plasma during the plasma CVD process. Accordingly, the temperature of the surface of the showerhead 30 becomes higher than that obtained in the thermal CVD process, by a certain difference of, e.g., about 10° C., although depending on the process temperature. This temperature difference brings about the jumping phenomenon on the first wafer, as described above.

In order to prevent the jumping phenomenon from occurring, where the pre-coat layer 28 consisting of a TiN film is formed by thermal CVD, a control is performed to cancel the temperature difference of 10° C. on the surface of the showerhead 30. Specifically, the temperature of the worktable 16 is set to be slightly higher, such as about 20° C. higher (i.e., 670° C.) in the above described case. The temperature of the surface of the showerhead 30 can be thereby almost the same as that obtained by a case where the Ti film formation process is performed by plasma CVD. As a consequence, it is possible to prevent the jumping phenomenon from occurring on the first wafer.

FIG. 7 is a graph showing the influence of the relationship between a pre-coat layer formation temperature and a wafer film formation temperature, on the pre-coat film thickness and inter-substrate uniformity. In FIG. 7, a line X stands for a case where the pre-coat layer formation temperature was set to be the same as the wafer film formation temperature. A line Y stands for a case where the pre-coat layer formation temperature was set to be higher than the wafer film formation temperature (fro example, higher by 10 to 30° C., and preferably by 15 to 25° C.). As indicated by the line Y, the inter-substrate uniformity in the film thickness and resistivity is higher, i.e., the reproducibility is improved, where the pre-coat layer formation temperature (e.g., 670° C.) is set to be slightly higher than the wafer film formation temperature (e.g., 650° C.) by, e.g., about 20° C.

In general, the processing apparatus is not necessarily continuously operated, such that, if there are no semiconductor wafers to be processed, it is not operated for a long period of time of, e.g., several hours to several days, while the worktable 16 has a pre-coat layer deposited thereon. In this case, the apparatus is set to be under a so-called idling operation, so that it can start a film formation process for a short period of time, as needed. Typically, during the idling operation of the apparatus the power supply is not turned off, and the worktable 16 is set at a high temperature while a small amount of inactive gas, such as Ar gas or N₂ gas, is kept supplied into the process container 4. The same state also appears after a maintenance operation.

The present inventors have found that there is case where the resistivity of a deposited film becomes larger on, e.g., the first to fifth wafers processed by a film formation process started after an idling operation. The resistivity is far larger, beyond the acceptable range, than the resistivity of a deposited film formed on the subsequent wafers.

In order to solve this problem, when a film formation process is restarted after an idling operation is performed for a short period of time or a long period of time, a stabilization process is performed, as follows. Specifically, immediately before a wafer is loaded, the cycle shown in FIG. 3A is performed at least once, wherein this cycle comprises a film formation step of forming a Ti film by plasma CVD, and a nitridation step of nitriding the Ti film to form a TiN-containing film. As a consequence, the surface of the pre-coat layer 28 is more effectively stabilized. Alternatively, the pre-coating process shown in any one of FIGS. 3B to 3D may be performed at least once for a short period of time, wherein this pre-coating process comprises a film formation step of forming a Ti film by thermal CVD. In any of these cases, the stabilization process is performed for a short period of time of about 5 seconds to 180 seconds, and preferably of 30 seconds to 60 seconds.

In this case, a thin TiN-containing film is deposited by the operation described above on the surface of the pre-coat layer which has been oxidized during the idling operation. As a consequence, the surface of the pre-coat layer is stabilized, so that the amount of radiant heat from the worktable 16 remains almost constant. As a consequence, it is possible to prevent the resistivity of a deposited film from becoming excessively larger on the first several wafers processed by the film formation process started after the idling operation, thereby improving the planar and inter-substrate uniformities.

FIG. 8 is a graph showing the resistivity of a deposited film obtained by film formation on the first wafer after the processing apparatus undergoes an idling operation for a long period of time. In FIG. 8, the first half shows experimental results obtained by a conventional apparatus, and the latter half shows experimental results obtained by an apparatus (one cycle of pre-coating was performed) according to this embodiment. In the example shown in FIG. 8, a cleaning operation was performed at suitable timing. Further, an idling operation had been performed for a long time, such as several hours, immediately before each plotted point.

As shown in FIG. 8, in the case of the conventional apparatus, the resistivity becomes larger at points X1 to X3, beyond the acceptable range. On the other hand, in the case of the apparatus according to this embodiment, the resistivity is always within the acceptable range. Specifically, even if the worktable inside the process container is provided with a pre-coat layer, the stabilization process performed for a short period of time prior to film formation allows the film formation process to be processed with high stability and reproducibility. The stabilization process is preferably performed before wafers are processed, without reference to the length of the idling operation.

### SECOND EMBODIMENT

In the embodiment described above, a pre-coating process is performed to stabilize the state inside the process container 4, immediately after a cleaning process is performed for the interior of the process container 4, or immediately before a wafer is loaded after the processing apparatus 2 undergoes an idling operation. In this case, it has been found that some problem arise if the pre-coating process comprises a Ti film formation process by plasma CVD and a nitridation process by plasma (particularly the cases shown in FIGS. 3A and 3D). Specifically, there is a case where the film quality is deteriorated by local electrical discharge damage on the first wafer subsequently loaded.

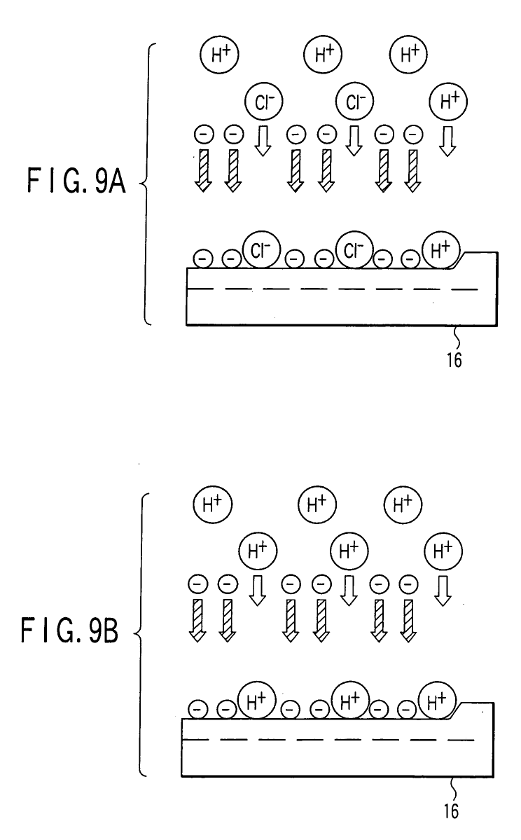

This electrical discharge is thought to be caused by the following mechanism. FIGS. 9A and 9B are explanatory diagrams showing the cause of electrical discharge occurring between a semiconductor wafer and a worktable. Specifically, as shown in FIG. 9A, when a Ti film is formed on the worktable 16 by plasma CVD using TiCl₄ gas and H₂ gas, the TiCl₄ gas is decomposed by plasma and generates negative ions of Cl (i.e., Cl⁻). The negative ions cause the surface of the worktable 16 to be charged with a negative charge. At this time, positive ions of H (i.e., H⁺) are also generated, but negative ions of Cl (i.e., Cl⁻) are dominant.

Then, as shown in FIG. 9B, a nitridation process is performed with NH₃ plasma, in which NH₃ is decomposed and generates positive ions of (i.e., H⁺). Although these positive ions electrically neutralize the surface of the worktable 16 to some extent, the surface of the worktable 16 is still charged with a negative charge.

Under such conditions, when a wafer is placed on the surface of the worktable 16 and a Ti film is formed on the wafer by plasma CVD, the wafer body is electrically charged at this time. As a consequence, electrical discharge occurs between the wafer W and the worktable 16 charged with strong negative charge, and particularly at the periphery where the charge tends to concentrate, thereby deteriorating the film quality at the periphery.

Specifically, as the process uses a process gas entailing more negative ions, the worktable 16 is more electrically changed. In this case, the potential difference between the worktable and a subsequently processed wafer becomes larger, and thus causes electrical discharge. Examples of a gas apt to generate negative ions are halogenated compounds, such as halogenated metals, e.g., TiCl₄ gas, and CF family gases. Such electrical discharge occurs only on the first processed wafer, and does not occur on the wafers subsequently processed in series.

In consideration of this, according to this embodiment, a stabilization process is performed to stabilize the state inside the process container 4, after the first process is performed by plasma CVD using a gas which brings about mostly first polarity ions by ionization within the process container. During the stabilization process, a stabilization process gas is supplied into the process container 4 and turned into plasma, wherein the stabilization process gas brings about mostly second polarity ions opposite the first polarity by ionization. The stabilization process electrically neutralizes the surface of the worktable 16 which has been electrically charged by the first process.

The above described example of the first process is a process for forming a CVD pre-coat layer to cover the top surface of the worktable 16, using a film formation gas. Another example of the first process is a process for forming a CVD film on a preceding substrate, using a film formation gas. In the latter case, it is typically supposed to set the apparatus under an idling operation between the first process and stabilization process.

In other words, when a wafer is processed after an idling operation of the processing apparatus, or when a wafer is processed after a pre-coating process, a stabilization process is performed to stabilize the surface of the worktable 16 immediately before the process of the wafer is started. As a consequence, the electrical charge on the surface of the worktable 16 is decreased and stabilized, and the material of the surface of the worktable 16 is also stabilized.

For example, this stabilization process can be performed by supplying a gas into the process container 4 and turning it into plasma, wherein the gas contains the same gases as the process gas used for a film formation process on a wafer, except that the metal-containing source gas is excluded therefrom. Specifically, according to this embodiment, the process gas excluding the metal-containing source gas or TiCl₄ gas is supplied, i.e., NH₃ gas, H₂ gas, and Ar gas are supplied, to generate plasma. As a consequence, a thin film on the surface of the worktable 16 is nitrided and reformed, and the charge (electrical charge amount) on the surface of the worktable 16 is decreased. Alternatively, a mixture gas of at least one of N₂, NH₃, and MMH gases with Ar gas may be used to perform a plasma process. This process is also effective for another metal-containing source gas, such as an organic-metal compound gas, e.g., TiI₄ gas or TaCl₅ gas.

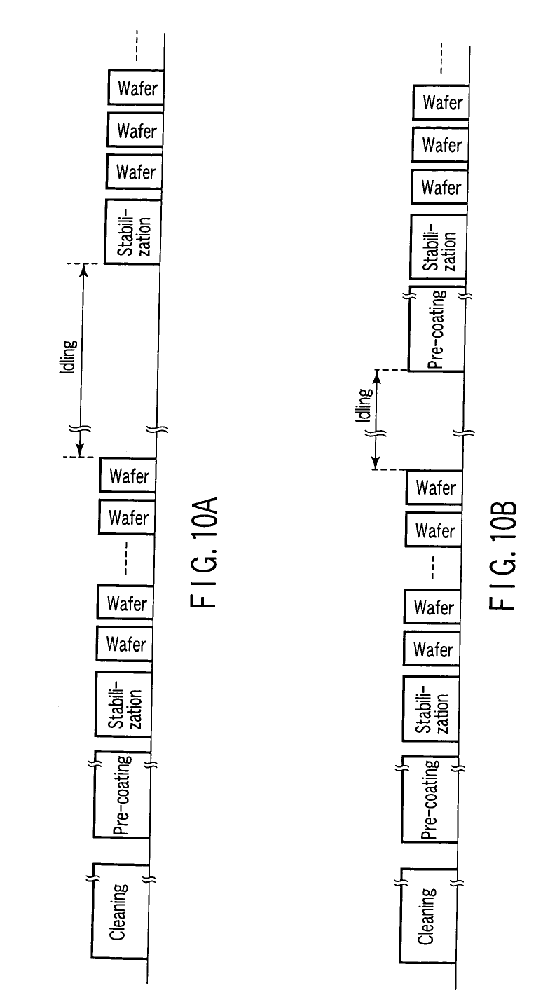

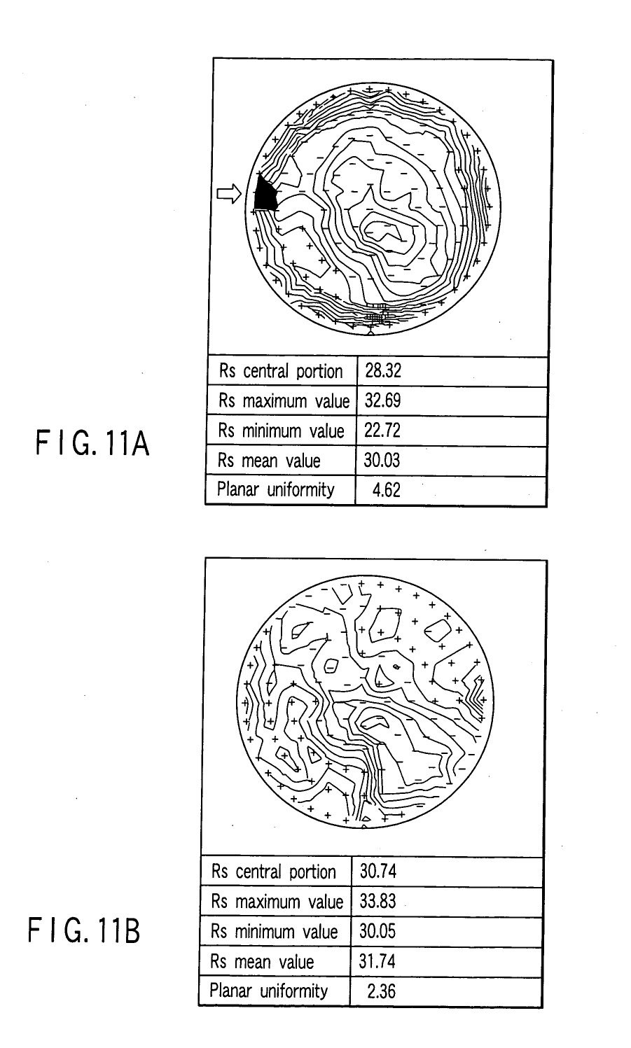

FIGS. 10A and 10B are time charts respectively showing different methods for performing a stabilization process. In the method shown in FIG. 10A, a stabilization process is performed between a process on the first wafer and a pre-coating process after a cleaning process, and is also performed immediately before the first wafer starts being processed after an idling operation I. In the method shown in FIG. 10B, a pre-coating process is performed again before a process on wafers starts after an idling operation I, and a stabilization process is performed between this pre-coating process and a process on the first wafer.

The idling operation of the apparatus may be set to automatically start when the blank time between two periods of the main film formation process on a target substrate is, e.g., 60 seconds or more. Typically, during the idling operation, the power supply of the apparatus is not turned off, and the worktable 16 is set at a high temperature while a small amount of inactive gas, such as Ar gas or N₂ gas, is kept supplied into the process container 4.

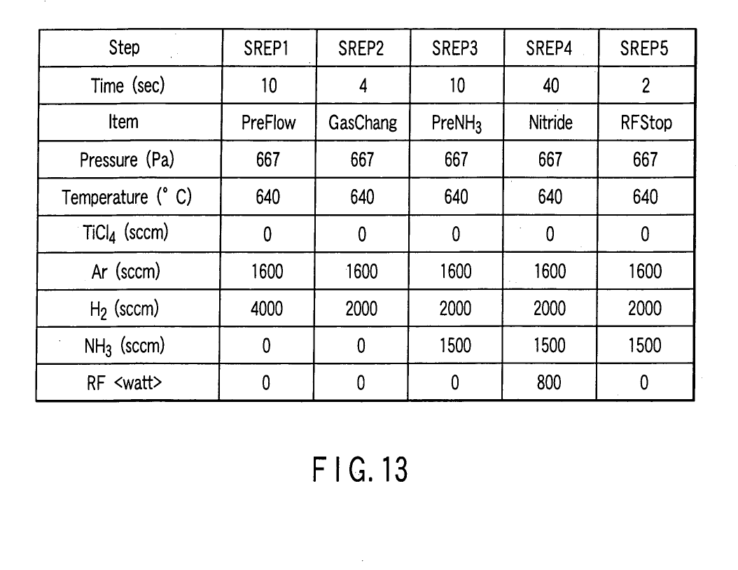

FIG. 13 is a diagram showing specific process conditions for the stabilization process. This stabilization process prevents abnormal electrical discharge from occurring between the worktable 16 and first wafer processed immediately after the stabilization process.

The steps in FIG. 13 comprise the same steps shown in FIG. 12, although the Ti film formation step by plasma CVD and steps associated therewith are excluded therefrom. As shown in FIG. 13, the process temperature is kept at a constant value of 640° C., and the process pressure is also kept at a constant value of 667 Pa.

It is assumed that, the worktable 16 first substantially reaches a predetermined process temperature. In STEP 1, i.e., “PreFlow”, Ar gas and H₂ gas are supplied into the process container 4, and their flow rates are stabilized. At this time, the flow rate of Ar gas is set to be 500 to 3,000 sccm, such as 1,600 sccm, and the flow rate of H₂ gas is set to be 1,000 to 5,000 sccm, such as 4,000 sccm. In STEP 2, i.e., “GasChang”, the flow rate of H₂ gas is decreased from 4,000 sccm to 2,000 sccm to prepare for supply of NH₃ gas in the next step. In STEP 3, i.e., “PreNH₃”, NH₃ gas starts being supplied and the gas flow rate is stabilized. The flow rate of NH₃ gas is set to be 500 to 3,000 sccm, such as 1,500 sccm.

In STEP 4, i.e., “Nitride”, the gas flow rate described above in STEP 3 is maintained. Then, an RF (radio frequency) is applied to the upper electrode or showerhead 30 to generate plasma in the process container 4. As a consequence, a film deposited on the surface of the worktable 16 is nitrided or reformed, and is stabilized. In this case, unlike the pre-coating process shown in FIGS. 3A to 3D, a Ti film formation process by plasma CVD is not performed. Accordingly, the surface of a worktable is not electrically charged with a negative charge. This process time is set to be 5 to 120 seconds, such as 40 seconds. Then, in STEP 5, i.e., “RFStop”, the application of RF is stopped.

One cycle consisting of these STEP 1 to STEP 5 may be repeated a plurality of times, or may be performed once. Immediately after this stabilization process, a film formation process is performed on ordinary wafers. This cycle may exclude STEP 1 and start from STEP 2 using it as pre-flow.

Since the surface of the worktable 16 is scarcely electrically charged, no problems arise when a Ti film is deposited on the first wafer by a plasma process. Specifically, the potential difference between the worktable 16 and wafer is not so large, thereby preventing electrical discharge from occurring therebetween. The stabilization process is preferably performed before a process on wafers without reference to the length of an idling operation.

FIGS. 11A and 11B are views showing the resistivity of a Ti film formed on the first wafer without the stabilization process and with the stabilization process, respectively. FIG. 11A shows the resistivity distribution when no stabilization process was performed. FIG. 11B shows the resistivity distribution when the stabilization process was performed.

In FIG. 11A, the black portion on the wafer periphery indicated by an arrow denotes a portion where a particular point of the resistivity (Rs) occurred (where the characteristic was remarkably deteriorated). In this case, the difference in resistivity between maximum and minimum is 9.97, and the planar uniformity is 4.62%.

On the other hand, in the case of FIG. 11B, no particular point of the resistivity occurred and the resistivity showed a good distribution. In this case, the difference in resistivity between maximum and minimum is 3.78, and the planar uniformity is 2.36%. Specifically, as compared to the result shown in FIG. 11A, the result shown in FIG. 11B has a remarkably improved planar uniformity.

The stabilization process may be added to any one of the film formation methods shown in FIGS. 3A to 3D. Further, the stabilization process may be performed in the case of metal-containing film formation by plasma CVD, or metal film or metal-containing film formation by thermal CVD, as well as metal film formation by plasma CVD on wafers.

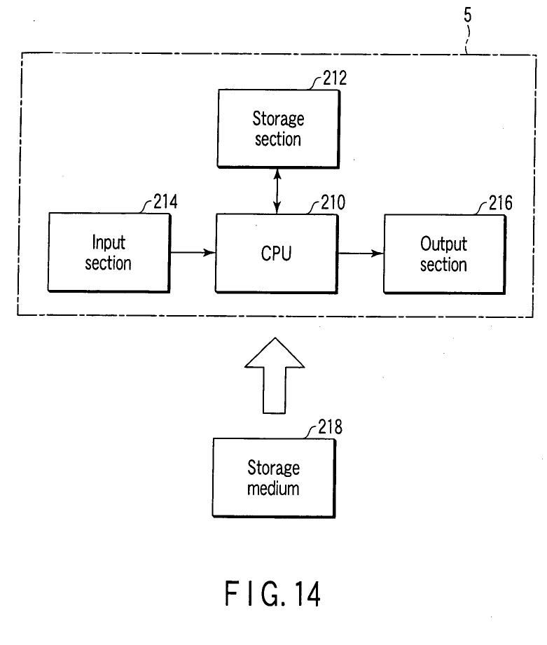

Each of the methods according to the embodiments described with reference to FIGS. 1 to 13 is performed under the control of the control section 5 (see FIG. 1) in accordance with a process program, as described above. FIG. 14 is a block diagram schematically showing the structure of the control section 5. The control section 5 includes a CPU 210, which is connected to a storage section 212, an input section 214, and an output section 216. The storage section 212 stores process programs and process recipes. The input section 214 includes input devices, such as a keyboard, a pointing device, and a storage media drive, to interact with an operator. The output section 216 outputs control signals for controlling components of the processing apparatus. FIG. 14 also shows a storage medium 218 attached to the computer in a removable state.

Each of the methods according to the embodiments described above may be written as program instructions for execution on a processor, into a computer readable storage medium or media to be applied to a semiconductor processing apparatus. Alternately, program instructions of this kind may be transmitted by a communication medium or media and thereby applied to a semiconductor processing apparatus. Examples of the storage medium or media are a magnetic disk (flexible disk, hard disk (a representative of which is a hard disk included in the storage section 212), etc.), an optical disk (CD, DVD, etc.), a magneto-optical disk (MO, etc.), and a semiconductor memory. A computer for controlling the operation of the semiconductor processing apparatus reads program instructions stored in the storage medium or media, and executes them on a processor, thereby performing a corresponding method, as described above.

The process conditions, such as gas flow rates, pressures, and temperatures, described above with reference to first and second embodiments are mere examples. Further, the structure of the processing apparatus is also a mere example. For example, the frequency of the power supply 56 for plasma generation may be set at a value other than 450 kHz. Alternatively, the plasma generation means may utilize a microwave.

In the first and second embodiments, a Ti film formation process is explained as an example. Alternatively, the present invention may be applied to a film formation process of a metal film, such as tungsten (W), or a metal-containing film, such as tungsten silicide (WSix), tantalum oxide (TaOx: Ta₂O₅), or TiN. Alternatively, the present invention may be applied to a film formation process of a TiN film, HfO₂ film, RuO₂ film, or Al₂O₃ film.

The size of semiconductor wafers may be any one of 6 inches (150 mm), 8 inches (200 mm), 12 inches (300 mm), or a size exceeding 12 inches (e.g., 14 inches). The target substrate is not limited to a semiconductor wafer, and it may be glass substrate or LCD substrate. The worktable heating means is not limited to a resistance heater, and it may be a heating lamp.

According to the present invention, there is provided a worktable device, film formation apparatus, and film formation method for a semiconductor process, which can improve at least the inter-substrate uniformity of a film formed on target substrates.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A worktable device configured to be installed in a film formation process container for a semiconductor process, the device comprising:
a worktable including a top surface to place a target substrate thereon, and a side surface extending downward from the top surface;
a heater disposed in the worktable and configured to heat the substrate through the top surface; and
a CVD pre-coat layer covering the top surface and the side surface of the worktable, the pre-coat layer having a thickness not less than a thickness which substantially saturates amount of radiant heat originating from heating of the heater and radiated from the top surface and the side surface.

2. A film formation apparatus for a semiconductor process, comprising:
a process container configured to accommodate a target substrate;
a gas supply section configured to supply a process gas into the process container;
a gas exhaust section configured to exhaust gas inside the process container;
a worktable disposed inside the process container and including a top surface to place the target substrate thereon, and a side surface extending downward from the top surface;
a heater disposed in the worktable and configured to heat the substrate through the top surface; and
a CVD pre-coat layer covering the top surface and the side surface of the worktable, the pre-coat layer having a thickness not less than a thickness which substantially saturates amount of radiant heat originating from heating of the heater and radiated from the top surface and the side surface.

3. The apparatus according to claim 2, wherein the pre-coat layer consists essentially of a metal-containing film.

4. The apparatus according to claim 3, wherein the pre-coat layer consists essentially of a TiN-containing film and has a thickness of 0.5 μm to 20 μm.

5. The apparatus according to claim 2, further comprising an excitation mechanism configured to generate plasma within the process container.

6. A film formation method for a semiconductor process, comprising:
preparing a film formation apparatus, which comprises a process container configured to accommodate a target substrate, a gas supply section configured to supply a process gas into the process container, a gas exhaust section configured to exhaust gas inside the process container, a worktable disposed inside the process container and including a top surface to place the target substrate thereon, and a side surface extending downward from the top surface, and a heater disposed in the worktable and configured to heat the substrate through the top surface;
performing a CVD process while supplying a pre-process gas into the process container, to form a CVD pre-coat layer covering the top surface and the side surface of the worktable, the pre-coat layer having a thickness not less than a thickness which substantially saturates amount of radiant heat originating from heating of the heater and radiated from the top surface and the side surface;
loading the substrate into the process container and placing the substrate on the top surface of the worktable, after forming the pre-coat layer; and
performing a main film formation process while supplying a main process gas into the process container, to form a film on the substrate placed on the worktable.

7. The method according to claim 6, wherein the pre-coat layer consists essentially of a metal-containing film.

8. The method according to claim 7, wherein the pre-coat layer consists essentially of a TiN-containing film and has a thickness of 0.5 μm to 20 μm.

9. The method according to claim 8, wherein forming the pre-coat layer comprises a film formation step of forming a Ti film by plasma CVD, and a nitridation step of nitriding the Ti film.

10. The method according to claim 8, wherein forming the pre-coat layer comprises a film formation step of forming a TiN film by thermal CVD.

11. The method according to claim 10, wherein the gas supply section comprises a showerhead disposed above the worktable,
the main film formation process is performed by plasma CVD, and
the worktable is set at a temperature in the thermal CVD to cause the showerhead to have a temperature substantially the same as that of the showerhead provided by the plasma CVD.

12. The method according to claim 10, wherein forming the pre-coat layer comprises a nitridation step.

13. The method according to claim 9, wherein forming the pre-coat layer is arranged to repeat each step a plurality of time.

14. The method according to claim 6, further comprising:
setting the film formation apparatus to be under an idling operation, after performing the main film formation process on the substrate;
performing a stabilization process to stabilize a state within the process container after the idling operation, wherein a CVD process is preformed for 5 seconds to 180 seconds while supplying the pre-process gas into the process container during the stabilization process;
loading a second substrate into the process container and placing the second substrate on the top surface of the worktable, after performing the stabilization process; and
performing a film formation process while supplying a process gas into the process container, to form a film on the second substrate placed on the worktable.

15. The method according to claim 6, wherein the pre-process gas is a gas that generates mostly negative ions by ionization, and
the method further comprises performing a stabilization process to stabilize a state within the process container, between forming the pre-coat layer and loading the substrate into the process container, wherein a stabilization process gas that generates mostly positive ions by ionization is supplied into the process container and turned into plasma during the stabilization process.

16. The method according to claim 6, wherein the main process gas is a gas that generates mostly negative ions by ionization, and the main film formation process is a process to form a film by plasma CVD, and
the method further comprises
setting the film formation apparatus to be under an idling operation, after performing the main film formation process on the substrate;
performing a stabilization process to stabilize a state within the process container after the idling operation, wherein a stabilization process gas that generates mostly positive ions by ionization is supplied into the process container and turned into plasma during the stabilization process;
loading a second substrate into the process container and placing the second substrate on the top surface of the worktable, after performing the stabilization process; and
performing a film formation process while supplying a process gas into the process container, to form a film on the second substrate placed on the worktable.

17. A film formation method for a semiconductor process, comprising:
preparing a film formation apparatus, which comprises a process container configured to accommodate a target substrate, a gas supply section configured to supply a process gas into the process container, a gas exhaust section configured to exhaust gas inside the process container, a worktable disposed inside the process container and including a top surface to place the target substrate thereon, and an excitation mechanism configured to generate plasma within the process container;
performing a first process by plasma CVD while supplying a first process gas into the process container, wherein the first process gas is a gas that generates ions mostly of a first polarity by ionization;
performing a stabilization process to stabilize a state within the process container after the first process, wherein a stabilization process gas that generates ions mostly of a second polarity opposite to the first polarity by ionization is supplied into the process container and turned into plasma during the stabilization process;
loading the substrate into the process container and placing the substrate on the top surface of the worktable, after the stabilization process; and
performing a main film formation process by plasma CVD while supplying a main process gas into the process container, to form a film on the substrate placed on the worktable.

18. The method according to claim 17, wherein the first process is a process to form a CVD pre-coat layer covering the top surface of the worktable.

19. The method according to claim 17, wherein the first process is a process to form a CVD film on a preceding substrate placed on the worktable.

20. The method according to claim 15, wherein the first process gas contains a halogenated metal gas, and the stabilization process gas contains an inactive gas.

21. The method according to claim 20, wherein the first process gas contains TiCl₄ gas, and the stabilization process gas contains a mixture gas of an inactive gas with a gas selected from the group consisting of N₂, NH₃, and monomethylhydrazine.

22. The device according to claim 1, wherein the pre-coat layer consists essentially of a metal-containing film.

23. The device according to claim 22, wherein the pre-coat layer consists essentially of a TiN-containing film and has a thickness of 0.5 μm to 20 μm.

24. The method according to claim 10, wherein forming the pre-coat layer is arranged to repeat each step a plurality of time.

25. A computer readable medium containing program instructions for execution on a processor, which when executed by the processor, cause a film formation apparatus for a semiconductor process to perform a film formation method, wherein the apparatus comprises a process container configured to accommodate a target substrate, a gas supply section configured to supply a process gas into the process container, a gas exhaust section configured to exhaust gas inside the process container, a worktable disposed inside the process container and including a top surface to place the target substrate thereon, and a side surface extending downward from the top surface, and a heater disposed in the worktable and configured to heat the substrate through the top surface, the method comprising:
performing a CVD process while supplying a pre-process gas into the process container, to form a CVD pre-coat layer covering the top surface and the side surface of the worktable, the pre-coat layer having a thickness not less than a thickness which substantially saturates amount of radiant heat originating from heating of the heater and radiated from the top surface and the side surface;
loading the substrate into the process container and placing the substrate on the top surface of the worktable, after forming the pre-coat layer; and
performing a main film formation process while supplying a main process gas into the process container, to form a film on the substrate placed on the worktable.

26. A computer readable medium containing program instructions for execution on a processor, which when executed by the processor, cause a film formation apparatus for a semiconductor process to perform a film formation method, wherein the apparatus comprises a process container configured to accommodate a target substrate, a gas supply section configured to supply a process gas into the process container, a gas exhaust section configured to exhaust gas inside the process container, a worktable disposed inside the process container and including a top surface to place the target substrate thereon, and an excitation mechanism configured to generate plasma within the process container, the method comprising:
performing a first process by plasma CVD while supplying a first process gas into the process container, wherein the first process gas is a gas that generates ions mostly of a first polarity by ionization;
performing a stabilization process to stabilize a state within the process container after the first process, wherein a stabilization process gas that generates ions mostly of a second polarity opposite to the first polarity by ionization is supplied into the process container and turned into plasma during the stabilization process;
loading the substrate into the process container and placing the substrate on the top surface of the worktable, after the stabilization process; and
performing a main film formation process by plasma CVD while supplying a main process gas into the process container, to form a film on the substrate placed on the worktable.
